(19) United States
(12) Patent Application Publication
(10) Pub. No.: US 2016/0121824 A1
(43) Pub. Date: May 5, 2016

(54) SOLAR POWER GENERATOR FOR WINDOW

(71) Applicants: HYUNDAI MOTOR COMPANY, Seoul (KR); KIA MOTORS CORPORATION, Seoul (KR)

(72) Inventors: Mi Yeon SONG, Seoul (KR); Sang Hak KIM, Seoul (KR); Won Jung KIM, Seoul (KR)

(21) Appl. No.: 14/927,243

(22) Filed: Oct. 29, 2015

(30) Foreign Application Priority Data
Nov. 3, 2014 (KR) 10-2014-0151086

(51) Int. Cl. B60R 16/03; H01L 31/048; H01L 31/0216; H01L 31/02; H01L 31/0224

(52) U.S. Cl. CPC B60R 16/03; H01L 31/0201; H01L 31/022433; H01L 31/02168; H01L 31/022475; H01L 31/022483; H01L 31/022466; H01L 31/048

(57) ABSTRACT

A solar power generator for a window includes a glass layer and a sunlight generation layer disposed over the glass layer. The sunlight generation layer is configured to generate electric current using sunlight transmitted through the glass layer. A protective film layer is configured to protect the sunlight generation layer. The sunlight generation layer includes a transparent conductive film provided over the glass layer, a transparent solar power generator active layer provided over the transparent conductive film, and a transparent counter electrode provided over the transparent solar power generator active layer.

### CROSS-REFERENCE TO RELATED APPLICATION

This application claims under 35 U.S.C. §119(a) the benefit of priority to Korean Patent Application No. 10-2014-0151086 filed on Nov. 3, 2014, the entire contents of which are incorporated herein by reference.

### TECHNICAL FIELD

The present disclosure relates to a solar power generator for a window. More particularly, it relates to a solar power generator for a window through which an application area of the solar power generator is increased and higher power output thereof is ensured by applying the solar power generator to a window for a vehicle in addition to a roof as in a related art.

### BACKGROUND

Generally, various studies have been proposed on an energy harvesting for a vehicle as the importance of improving fuel ratio and using environment friendly energy emerges.

Currently, a silicon solar power generator is installed on a roof in some cases of vehicles so as to be applied as a parking ventilation system. However, the output of the solar power generator installed on a roof for a vehicle is not high and thus the application fields thereof are limited, and an open feeling is not sensed in a case of a silicon solar power generator of an opaque type and thus is undesirable to customer who is concerned with the open feeling of a panorama roof. Accordingly, the silicon solar power generator can be applied to an opaque part of a vehicle but cannot be applied to a part that is desired to be transparent in a design of a vehicle.

Meanwhile, when a solar power generator using a photo-active substance with IR band of sun light is applied to all windows for a vehicle, higher power output can be ensured and further the solar power generator can be applied to various fields.

In this regard, the energy of sun light arriving on an earth consists of about 10% of ultraviolet rays, 45% of visible light and 45% of infrared light. Here, a commonly used solar power generator uses the visible light band and is configured as being opaque or translucent type; however, there is a need to develop a solar power generator of a transparent type so as to be applied to a window for a vehicle.

Accordingly, when power is generated using a solar power generator with infrared light (especially NIR-IR band) making 45% of sun light, the solar power generator can be applied to a window for a vehicle.

If a solar power generator uses an organic substance that has a transmission rate of 50% or more and absorbs light at a band of 650-950 nm, a thin film solar power generator can be applied as an open type.

It can be confirmed from below sources that some organic photovoltaic cells study cell units using organic materials that absorbs light at a band of NIR-IR as an intended compromise technology.
[Source 1] Appl, Phys. Lett. 99. 193307 (2011)
[Source 2] Appl, Phys. Lett. 98. 113305 (2011)

Further, Korean Patent Publication No. 10-2013-0034996 has disclosed a technology of “Solar Power Generator for Vehicle and Method for Manufacturing the Same”, corresponding to the intention in the forgoing wherein according to a related art, electric energy is produced by arranging a solar power generator module in which a transparent conducting film is formed and the transparent conducting film is patterned to form a texture on a glass on a door side, a rear glass, an upper roof panel and a trunk panel even while a vehicle drives such that a crystalline solar power generator module is prepared by forming a Transparent Conducting Oxide film, firstly laser-patterning the transparent conducing oxide film to have a texture, forming an amorphous film layer by laminating or depositing an amorphous silicon film over the transparent conducting oxide film, secondly laser patterning the transparent conducting oxide film over which the amorphous film layer is deposited to form a conducting body to be laminated, and thirdly laser patterning the conducting body to form a texture; a Vehicle Integrated Photovoltaic Module for allowing produced power to be charged into a battery of a vehicle is prepared by controlling a transparency degree of the solar power generator module and laminating a reinforcement glass on an upper or lower part thereof, and connecting a positive (+) electrode and negative (−) electrode to the solar power generator module and connecting these electrodes to a battery of a vehicle; and the vehicle integrated photovoltaic module is installed on a glass at a door side, a rear glass, an upper roof panel and a trunk panel.

A study is being made on preparing a transparent solar power generator by manufacturing a thin film type solar power generator in an open type by some companies. ([Source 3] WYSIPS company)

The above information disclosed in this Background section is only for enhancement of understanding of the background of the invention and therefore it may contain information that does not form the prior art that is already known in this country to a person of ordinary skill in the art.

### SUMMARY

The present disclosure has been made in an effort to solve the above-described problems associated with prior art. One object of an embodiment of the present invention relates to providing a solar power generator for a window, which generates electric power by absorbing a part wavelength of sunlight that transmits through the window to ensure a sunlight energy, and in which a collector electrode is utilized, thereby preventing resistance increasing and lower loss as the area to which the transparent solar power generator is applied increases and further maximizing current collection effect while maintaining transparency.

In one aspect, a solar power generator for a window includes a glass layer and a sunlight generation layer disposed over the glass layer. The sunlight generation layer is configured to generate electric current using sunlight transmitted through the glass layer. A protective film layer is configured to protect the sunlight generation layer. The sunlight generation layer includes a transparent conductive film provided over the glass layer, a transparent solar power generator active layer provided over the transparent conductive film, and a transparent counter electrode provided over the transparent solar power generator active layer.

In certain embodiments, the transparent solar power generator active layer may be provided with a collector electrode including a plurality of finger lines extending in a length direction of the glass layer and disposed at a regular interval. The finger lines may be configured to send the electric current generated through the transparent solar power generator active layer. The finger lines may have opposing first and second ends in the length direction, and a bus bar may connect the first ends of the finger lines and collect and send the electric current that is sent through the finger lines.

In certain embodiments, the glass layer may have a heated wire provided as a matrix on an upper surface of the glass layer. In certain embodiments, the finger lines may be of same configuration and size as the heated wire of the glass layer.

In certain embodiments, the solar power generator may further include a near infrared (NIR) reflection layer provided between the sunlight power generation layer and the protective film layer. The NIR reflection layer may be configured to reflect near infrared light while maintaining transparency of the sunlight power generation layer. In certain embodiments, the collector electrode may have a pattern formed by laser using at least one of ITO, IZO, ZnO and FTO.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The above and other features of the invention are discussed infra.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a cross-sectional view illustrating a solar power generator for a window according to a first embodiment of the present invention;

FIG. 2 is a side view illustrating the solar power generator for a window according to the first embodiment of the present invention;

FIG. 3 is a cross-sectional view illustrating a solar power generator for a window according a second embodiment of to the present invention;

FIG. 4 is a side view illustrating the solar power generator for a window according to the second embodiment of the present invention; and

FIG. 5 is a cross-sectional view illustrating a solar power generator for a window according to a third embodiment of the present invention.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

A solar power generator for a window 100 (Hereinafter, referred to as “solar power generator”) of the present invention uses a collector electrode 130 so as to prevent an power output loss which is caused from the fact that a surface resistance increases as an area of a window to which the solar power generator is applied increase wherein the collector electrode utilizes mainly a metal material and thus it needs to design a structure of the electrode capable of maximizing current collection while maintain transparency.

That is, the present disclosure has proposed solutions regarding a structure of the transparent solar power generator 100 and a structure design of the collector electrode 130 which are applied to a window of a vehicle, and further it is emphasized that embodiments of the present invention can be applied to various glasses such as glass that is used in an entire industry, window, fire proof glass and the like.

Further, the transparent solar power generator 100 may be applied to all windows of a vehicle and may be prepared in a bonding type and an integrated type as a proper structure.

### Embodiment 1

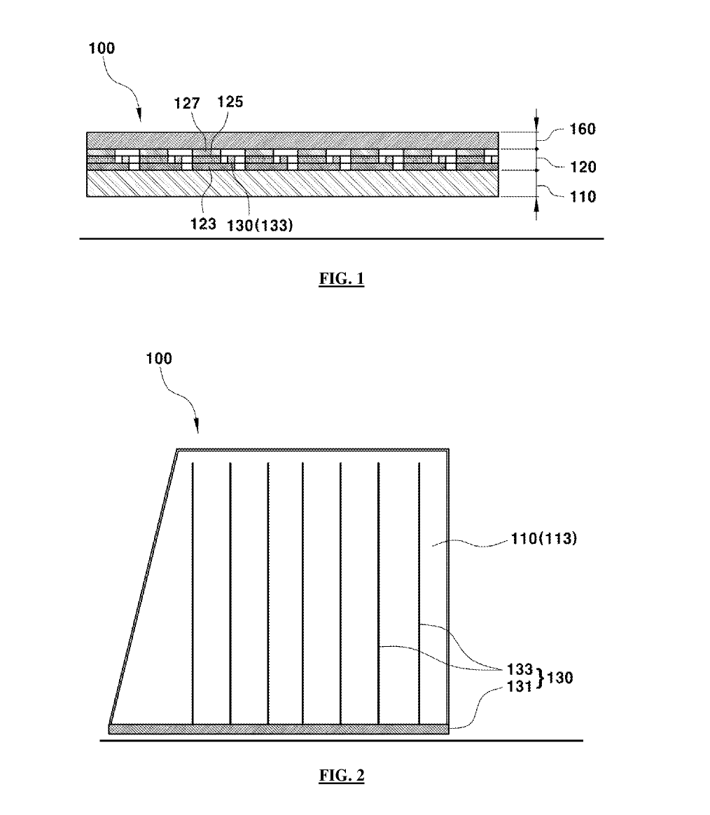

The solar power generator 100 of the present invention includes a glass layer 110, a sunlight generation layer 120 that is disposed over the glass layer 110 and generates electric current by using sunlight transmitted through the glass layer 110 and a protective film layer 160 for protecting the sunlight generation layer 120, as shown in FIGS. 1 and 2.

In certain embodiments, the sunlight generation layer 120 is prepared by forming a transparent solar power generator active layer 125 over a transparent conductive film 123 as a base layer and forming a transparent counter electrode 127 over the transparent solar power generator active layer.

In certain embodiments, a collector electrode 130 is further provided on the transparent solar power generator active layer 125. The collector electrode 130 is comprised of a plurality of finger lines 133 that are extended along a length direction of the glass layer 110 and disposed continuously at a same interval, and a bus bar 131 that connects ends of the finger lines 133 at one side and sends the electric current generated through the transparent solar power generator active layer 125. In certain embodiments, the bus bar may connect the ends of all of the finger lines.

### Embodiment 2

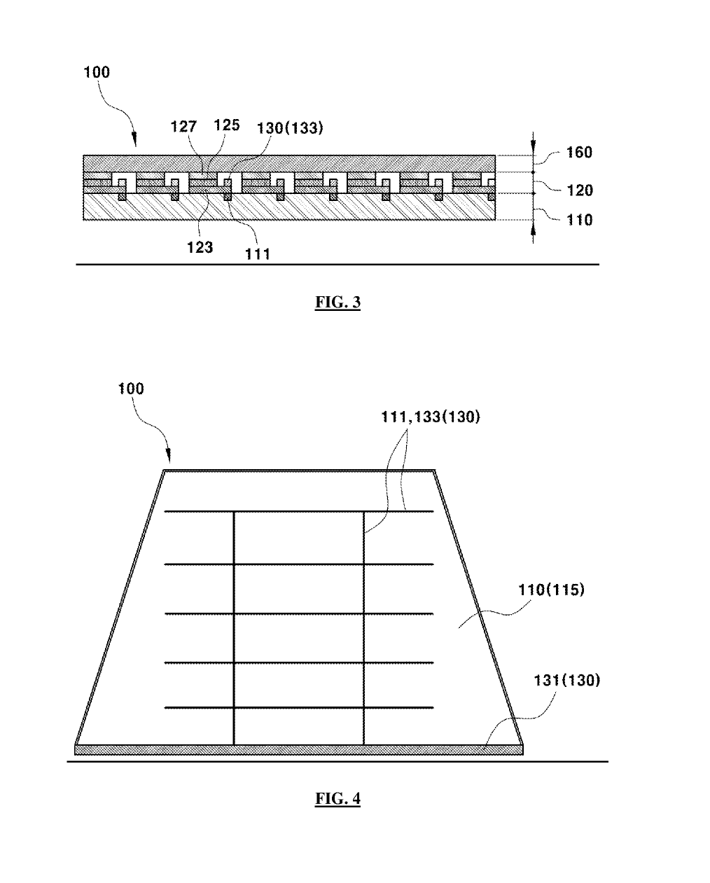

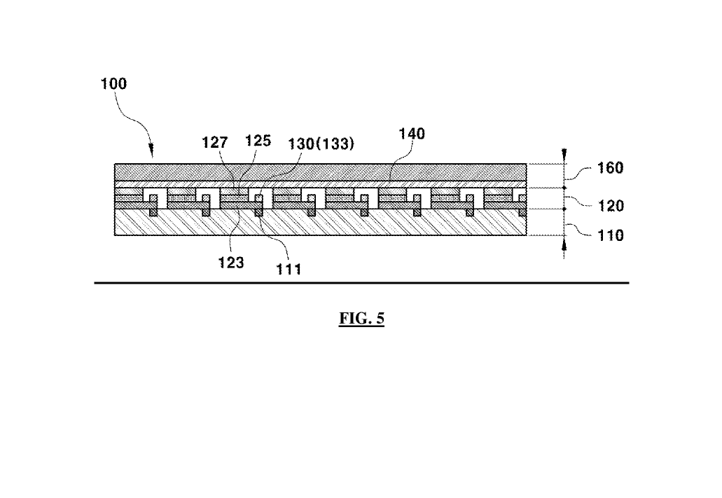

In another embodiment, the solar power generator 100 of the present invention includes a glass layer 110 having a heated wire 111 provided as matrix on an upper surface, a sun light generation layer 120 that is disposed over the glass layer 110 and generates electric current by sunlight transmitted through the glass layer 110 and a protective film layer 160 for protecting the sunlight generation layer 120, as shown in FIGS. 3 and 4.

In certain embodiments, the sunlight generation layer 120 is prepared by forming a transparent solar power generator active layer 125 over a transparent conductive film as a base layer and forming a transparent counter electrode 127 over the transparent solar power generator active layer.

In certain embodiments, a collector electrode 130 is further provided on the transparent solar power generator active layer 125. The collector electrode 130 is comprised of a plurality of finger lines 133 that are extended along a length direction of the glass layer 110 and disposed at a same interval and a bus bar 131 that connects ends of the finger lines 133 at one side and sends the electric current generated through the transparent solar power generator active layer 125. In certain embodiments, the bus bar may connect the ends of all of the finger lines.

In certain embodiments, the finger lines 133 may be formed in a matrix shape corresponding to the matrix shape of the heated wire 111 of the glass layer 110. In certain embodiments, the finger lines 133 may overlap with the heated wire 111. In certain embodiments, the finger lines 133 may have the same shape as the matrix of the heated wire 111. In certain embodiments, the finger lines 133 having the same matrix shape as that of the heated wire 111 may be positioned in the transparent solar power generator active layer 125 in a position corresponding to the position of the matrix of the heated wire 111 on the glass layer 110.

### Embodiment 3

In certain embodiments, the solar power generator 100 of the present invention further includes a near infrared (NIR) reflection layer 140 between the sunlight power generation layer 120 and the protective film layer 160. The NIR reflection layer 140 is configured to reflect near infrared while maintaining transparency of the sunlight power generation layer 120, as shown in FIG. 5, in addition to the elements included in Embodiments 1 and 2.

In certain embodiments, the NIR reflection layer 140 is a NIR dielectric mirror and has a reflection rate of 99% or more about most near infrared laser in a range of 700-900 nm, has a compatibility with helium-neon laser produced in a tube where mirror having a diameter of 1.0 inch (25.4 cm) is arranged, and has a high reflection rate at 633 nm. In certain embodiments, a commercially available NIR dielectric mirror such as Newport Corporation's model 5102 may be used as the NIR reflection layer.

The solar power generator 100 of embodiments of the present invention uses a collector electrode 130 so as to be applied to a large area through which sunlight is transmitted such as a side door window glass 113 and heated rear window glass 115 that are applied as a vehicle window.

That is, a technology is needed for maintaining transparency while increasing a current collection efficiency so as for the solar power generator to be applied to the vehicle window. In certain embodiments, the finger lines 133 are designed along the heated wires 111 in a heated rear window glass 115. In certain embodiments, such as in a case of a side door window glass 113 which needs to be transparent, the finger lines 133 are made of transparent material not to inhibit view sight.

In certain embodiments, the transparent electrode that is used on a vehicle window to which the solar power generator 100 of embodiments of the present invention is applied may use ITO (Indium Tin Oxide), IZO (Indium Zinc Oxide), ZnO (Zinc Oxide), FTO (Fluorine Tin doped Oxide) or the like. In certain embodiments, a short circuit may be formed between electrodes using laser and the collector electrode 130 and the transparent solar power generator active layer 125 may printed on the transparent electrode.

In certain embodiments, the solar power generator 100 is made of organic material that absorbs light at a range of 650 nm-900 nm NIR-IR and the electrodes may be printed using various printing methods such as a screen printing, an ink jet process, a spray printing or the like.

Further, in certain embodiments, the transparent counter electrode 127 is printed over the collector electrode 130 and the transparent solar power generator active layer 125 and finally the transparent protective is deposited thereon, thereby protecting the solar power generator 100 from being damaged and improving safety and commerciality thereof.

The solar power generator 100 prepared by the way described in the forgoing and applied to a vehicle window may have, in certain embodiments, a thickness of 100 nm at a maximum level from the transparent conductive film 123 to the transparent conductive electrode 127, and, in certain embodiments, a thickness of the transparent protective film 160 may be 0.5 mm at a maximum level to secure best stability.

Meanwhile, the collector electrode 130 used in embodiments of the present invention is provided with a plurality of finger lines 133 and bus bars 131 wherein in case of the bus bar 131 a large amount of electric current passes therethrough and it may be opaque since it is not exposed outside and further in case of the finger line 133 it is disposed on an edge of a window and it needs to be transparent for sunlight to be transmitted therethrough since it is printed on the window. Therefore, in certain embodiments, the finger line may include metal nano particles.

In certain embodiments, a metal material having best conductivity may be used for the collector electrode 130 and silver particles each having a size of 1 nm-10 nm may be used. In certain embodiments, the collector electrode may be printed by using various printing methods such as a screen printing, an ink jet process, a stamp printing, a roll-to-roll printing or the like.

Further, a transmittance or transparency of the collector electrode may be varied depending on a thickness, height and width of the printing pattern of a silver electrode even when same solution is used. In certain embodiments, the silver ink solution is prepared by dispersing silver nano particles into an organic solvent such as Ethylene glycol and is dried at 200° C. after being printed on the electrode.

In certain embodiments, the collector electrode 130 as configured in the forgoing may be formed on a vehicle window, or an integrated solar window may be prepared by coating the active layer substance of the solar power generator 100 on the vehicle window. Further, the solar power generator of the present invention may be used as an assistant power source that is accompanied in various industrial fields.

When electric power is generated using NIR-IR region of Infrared constituting 45% of sunlight with the solar power generator of the present invention as configured in the forgoing, a transparent solar power generator is applied to a vehicle window, thereby preventing resistance increasing and lower loss as the area to which the transparent solar power generator is applied increases and further maximizing current collection effect while maintaining transparency by applying a collector electrode.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A solar power generator for a window, the solar power generator comprising:
a glass layer;
a sunlight generation layer disposed over the glass layer and configured to generate electric current using sunlight transmitted through the glass layer; and
a protective film layer configured to protect the sunlight generation layer,
wherein the sunlight generation layer comprises: a transparent conductive film provided over the glass layer; a transparent solar power generator active layer provided over the transparent conductive film; and a transparent counter electrode provided over the transparent solar power generator active layer.

2. The solar power generator of claim 1, wherein the transparent solar power generator active layer is provided with a collector electrode comprising
a plurality of finger lines extending in a length direction of the glass layer and disposed at a regular interval, the finger lines configured to send the electric current generated through the transparent solar power generator active layer, the finger lines having opposing first and second ends in the length direction; and
a bus bar connecting the first ends of the finger lines and configured to collect and send the electric current that is sent through the finger lines.

3. The solar power generator of claim 1, further comprising a near infrared (NIR) reflection layer provided between the sunlight power generation layer and the protective film layer, the NIR reflection layer configured to reflect near infrared light while maintaining transparency of the sunlight power generation layer.

4. The solar power generator of claim 2, wherein the collector electrode has a pattern formed by laser using one of ITO, IZO, ZnO and FTO.

5. A solar power generator for a window, the solar power generator comprising:
a glass layer having a heated wire provided as a matrix on an upper surface of the glass layer.
a sun light generation layer disposed over the glass layer and configured to generate electric current using sunlight transmitted through the glass layer; and
a protective film layer configured to protect the sunlight generation layer,
wherein the sunlight generation layer comprises: a transparent conductive film provided over the glass layer; a transparent solar power generator active layer provided over the transparent conductive film; and a transparent counter electrode provided over the transparent solar power generator active layer.

6. The solar power generator of claim 5, wherein the transparent solar power generator active layer is provided with a collector electrode comprising:
a plurality of finger lines extending in a length direction of the glass layer and disposed at a regular interval, the finger lines configured to send the electric current generated through the transparent solar power generator active layer, the finger lines having opposing first and second ends in the length direction; and
a bus bar connecting the first ends of the finger lines and configured to collect and send the electric current that is sent through the finger lines.

7. The solar power generator of claim 5, further comprising a near infrared (NIR) reflection layer provided between the sunlight power generation layer and the protective film layer, the NIR reflection layer configured to reflect near infrared light while maintaining transparency of the sunlight power generation layer.

8. The solar power generator of claim 6, wherein the collector electrode has a pattern formed by laser using at least one of ITO, IZO, ZnO and FTO.

9. The solar power generator of claim 6, wherein the finger lines are of same configuration and size as the heated wire of the glass layer.
